(19) United States
(12) Patent Application Publication
(10) Pub. No.: US 2024/0213309 A1
(43) Pub. Date: Jun. 27, 2024

(54) SEMICONDUCTOR DEVICE, SEMICONDUCTOR CIRCUIT, AND METHOD OF CONTROLLING SEMICONDUCTOR DEVICE

(71) Applicant: Mitsubishi Electric Corporation, Tokyo (JP)

(72) Inventors: Atsushi ITO, Tokyo (JP); Manabu YOSHINO, Tokyo (JP); Toshihiro IMASAKA, Tokyo (JP); Masanori TSUKUDA, Tokyo (JP)

(73) Assignee: Mitsubishi Electric Corporation, Tokyo (JP)

(21) Appl. No.: 18/480,152

(22) Filed: Oct. 3, 2023

(30) Foreign Application Priority Data
Dec. 22, 2022 (JP) 2022-205332

(51) Int. Cl. H01L 29/06; H01L 27/06

(52) U.S. Cl. CPC H01L 29/0615; H01L 27/0635

(57) ABSTRACT

A semiconductor device includes a first conductive portion provided on a part of a second semiconductor layer via a first insulating film, a second conductive portion provided on a part of a third semiconductor layer via a second insulating film, a first main electrode, and a second main electrode. When an ON control signal is input to one of the first conductive portion and the second conductive portion, conduction is established between the first main electrode and the second main electrode by a bipolar operation, and when the ON control signal is input to both the first conductive portion and the second conductive portion, conduction is established between the first main electrode and the second main electrode by a unipolar operation.

### BACKGROUND OF THE INVENTION

### Field of the Invention

The present disclosure relates to a semiconductor device, a semiconductor circuit, and a method of controlling a semiconductor device.

### Description of the Background Art

As means for supplying drive power to a high voltage IC (HVIC) without adding a power supply, a bootstrap circuit combining an external bootstrap diode (BSD) and a capacitor is often used. In recent years, it has been proposed to use a semiconductor device with a built-in BSD in which a breakdown voltage maintaining region inside an HVIC has a BSD function instead of the external BSD (for example, refer to Yo Habu, et al., “Built-in BootStrap Diode Function Half-bridge Driver High Voltage (600 V) Integrated Circuit “M81777FP””, Mitsubishi Electric Technical Journal, Mitsubishi Electric Corporation, March 2022, Vol. 96, No. 3, P.156-P.159). According to such a configuration, since it is not necessary to provide an external BSD, it is possible to reduce the number of parts and to facilitate design.

In a conventional semiconductor device with a built-in BSD that performs a unipolar operation, the N-type diffusion layer serving as a breakdown voltage maintaining region for maintaining a high-breakdown voltage needs to be completely depleted, so that the concentration of impurities in the N-type diffusion layer is limited. As a result, there is the problem that it is difficult to reduce the ON resistance. In addition, in such a semiconductor device with a built-in BSD, if the length in the plane direction of the semiconductor device with a built-in BSD is increased in order to reduce the ON resistance, there arises another problem that the chip area and the size of the device increase.

### SUMMARY

The present disclosure has been made in view of the above problems, and an object of the present disclosure is to provide a technique capable of reducing the ON resistance of a semiconductor device.

A semiconductor device according to the present disclosure includes: a base layer made of a semiconductor of a first conductivity type or an insulator; a first semiconductor layer of a second conductivity type provided on the base layer; a second semiconductor layer of the first conductivity type and a third semiconductor layer of the first conductivity type provided separately from each other on an upper portion of the first semiconductor layer; a fourth semiconductor layer of the second conductivity type provided on an upper portion of the second semiconductor layer and sandwiching a part of the second semiconductor layer with the first semiconductor layer; a fifth semiconductor layer of the second conductivity type provided on an upper portion of the third semiconductor layer and sandwiching a part of the third semiconductor layer with the first semiconductor layer; an insulating layer provided on an upper portion of the first semiconductor layer between the second semiconductor layer and the third semiconductor layer; a first conductive portion provided on the part of the second semiconductor layer via a first insulating film; a second conductive portion provided on the part of the third semiconductor layer via a second insulating film; a first main electrode electrically connected to the second semiconductor layer and the fourth semiconductor layer; and a second main electrode electrically connected to the third semiconductor layer and the fifth semiconductor layer, wherein when an ON control signal is input to one of the first conductive portion and the second conductive portion, conduction is established between the first main electrode and the second main electrode by a bipolar operation, and when the ON control signal is input to both the first conductive portion and the second conductive portion, conduction is established between the first main electrode and the second main electrode by a unipolar operation.

The ON resistance of the semiconductor device can be reduced.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view illustrating a configuration of a semiconductor device according to a first preferred embodiment;

FIG. 2 is a cross-sectional view illustrating a configuration of a related device;

FIG. 3 is a view illustrating an input of a control signal according to the first preferred embodiment;

FIG. 4 is a cross-sectional view illustrating a configuration of a semiconductor device according to a second preferred embodiment;

FIG. 5 is a cross-sectional view illustrating a configuration of a semiconductor device according to a third preferred embodiment;

FIG. 6 is a cross-sectional view illustrating a configuration of a semiconductor device according to a fourth preferred embodiment;

FIG. 7 is a perspective view illustrating the configuration of the semiconductor device according to the fourth preferred embodiment;

FIG. 8 is a cross-sectional view illustrating a configuration of a semiconductor device according to a fifth preferred embodiment;

FIG. 9 is a cross-sectional view illustrating a configuration of a semiconductor device according to a sixth preferred embodiment;

FIG. 10 is a cross-sectional view illustrating a configuration of a semiconductor device according to a seventh preferred embodiment;

FIG. 11 is a cross-sectional view illustrating a configuration of a semiconductor device according to an eighth preferred embodiment;

FIG. 12 is a cross-sectional view illustrating a configuration of a semiconductor device according to a ninth preferred embodiment;

FIG. 13 is a circuit diagram illustrating a semiconductor circuit including a general bootstrap circuit;

FIG. 14 is a circuit diagram illustrating a semiconductor circuit according to a tenth preferred embodiment; and

FIG. 15 is a view for explaining a method of controlling a semiconductor device according to an eleventh preferred embodiment.

### DESCRIPTION OF THE PREFERRED EMBODIMENTS

Hereinafter, preferred embodiments will be described with reference to the accompanying drawings. Features described in the following preferred embodiments are examples, and all features are not necessarily essential. In the following description, similar components in a plurality of preferred embodiments are denoted by the same or similar reference numerals, and different components will be mainly described. Furthermore, in the following description, specific positions and directions such as “upper”, “lower”, “left”, “right”, “front”, or “back” may not necessarily coincide with actual positions and directions in practice. In addition, the fact that a certain portion has a higher concentration than another portion means that, for example, the average of the concentrations of the certain portion is higher than the average of the concentrations of the other portions. Conversely, the fact that a certain portion has a lower concentration than another portion means that, for example, the average of the concentrations of the certain portion is lower than the average of the concentrations of the other portions. In the following description, it is assumed that a first conductivity type is p-type and a second conductivity type is n-type, but the first conductivity type may be n-type and the second conductivity type may be p-type.

### First Preferred Embodiment

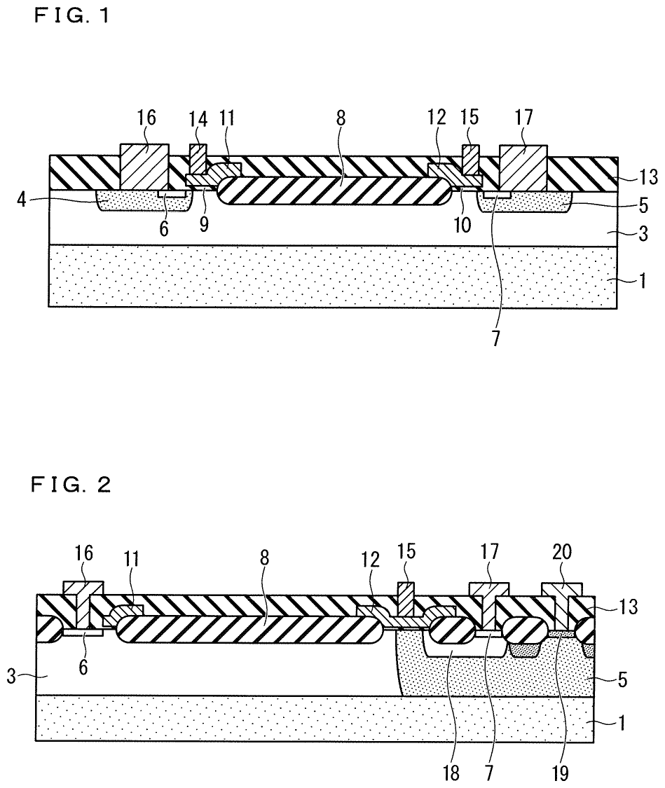

FIG. 1 is a cross-sectional view illustrating a configuration of a semiconductor device according to the present first preferred embodiment. The semiconductor device in FIG. 1 is a lateral high breakdown voltage semiconductor device that can be used as BSD.

The semiconductor device of FIG. 1 includes a P-type support substrate 1 of a first conductivity type, an N-type semiconductor layer 3 which is a first semiconductor layer of a second conductivity type, a P-type diffusion layer 4 and a P-type diffusion layer 5 which are a second semiconductor layer and a third semiconductor layer of the first conductivity type, and an N-type diffusion layer 6 and an N-type diffusion layer 7 which are a fourth semiconductor layer and a fifth semiconductor layer of the second conductivity type. In addition, the semiconductor device of FIG. 1 includes an insulating layer 8, a first insulating film 9, a second insulating film 10, a first conductive layer 11 and a first control electrode 14 included in a first conductive portion, a second conductive layer 12 and a second control electrode 15 included in a second conductive portion, an insulating layer 13, a first main electrode 16, and a second main electrode 17.

The P-type support substrate 1 is a base layer including a semiconductor of a first conductivity type as a material. The base layer may be a P-type epitaxial layer instead of the P-type support substrate 1.

The N-type semiconductor layer 3 is provided on the P-type support substrate 1. The N-type semiconductor layer 3 may be an epitaxial layer formed on the P-type support substrate 1 or a diffusion layer provided by diffusing impurities into the P-type support substrate 1. The material of the N-type semiconductor layer 3 may be normal silicon (Si), or may be a wide band gap semiconductor such as silicon carbide (SiC), gallium nitride (GaN), or diamond. In a case where the N-type semiconductor layer 3 is formed of a wide band gap semiconductor, stable operation under high temperature and high voltage, and high switching speed can be achieved.

The P-type diffusion layer 4 and the P-type diffusion layer 5 are provided on an upper portion of the N-type semiconductor layer 3 to be separated from each other. The N-type diffusion layer 6 is provided on an upper portion of the P-type diffusion layer 4, and sandwiches a part of the P-type diffusion layer 4 with the N-type semiconductor layer 3. The N-type diffusion layer 7 is provided on an upper portion of the P-type diffusion layer 5, and sandwiches a part of the P-type diffusion layer 5 with the N-type semiconductor layer 3. The insulating layer 8 is provided on an upper portion of the N-type semiconductor layer 3 between the P-type diffusion layer 4 and the P-type diffusion layer 5. In the example of FIG. 1, the insulating layer 8 is located between an end of the P-type diffusion layer 4 close to the N-type diffusion layer 6 and an end of the P-type diffusion layer 5 close to the N-type diffusion layer 7.

The first conductive layer 11 is provided on the part of the P-type diffusion layer 4 sandwiched between the N-type semiconductor layer 3 and the N-type diffusion layer 6 via the first insulating film 9. The first conductive layer 11 may also be provided on at least one of the N-type semiconductor layer 3 and the N-type diffusion layer 6 via the first insulating film 9, or may also be provided on the insulating layer 8. In the present specification, for example, at least one of A, B, C, . . . , and Z includes any one of all combinations of one or more extracted from the group of A, B, C, . . . , and Z.

The second conductive layer 12 is provided on the part of the P-type diffusion layer 5 sandwiched between the N-type semiconductor layer 3 and the N-type diffusion layer 7 via the second insulating film 10. The second conductive layer 12 may also be provided on at least one of the N-type semiconductor layer 3 and the N-type diffusion layer 7 via the second insulating film 10, or may also be provided on the insulating layer 8.

The insulating layer 13 covers the N-type semiconductor layer 3, the insulating layer 8, the first conductive layer 11, and the second conductive layer 12. In FIG. 1, the first insulating film 9, the second insulating film 10, and the insulating layer 13 are the same member, but may be individual members.

The first control electrode 14 is electrically connected to the first conductive layer 11 through a contact hole of the insulating layer 13, and the second control electrode 15 is electrically connected to the second conductive layer 12 through a contact hole of the insulating layer 13. In FIG. 1, the first control electrode 14 and the first conductive layer 11 are individual members, but may be the same member. Similarly, in FIG. 1, the second control electrode 15 and the second conductive layer 12 are individual members, but may be the same member.

The first main electrode 16 is electrically connected to the P-type diffusion layer 4 and the N-type diffusion layer 6 through a contact hole of the insulating layer 13, and the second main electrode 17 is electrically connected to the P-type diffusion layer 5 and the N-type diffusion layer 7 through a contact hole of the insulating layer 13.

In the semiconductor device according to the present first preferred embodiment, an ON control signal is input to each of the first control electrode 14 and the second control electrode 15 from a control unit that is not illustrated. As will be described later, in the semiconductor device according to the present first preferred embodiment, a bipolar operation is performed when the ON control signal is input to one of the first control electrode 14 and the second control electrode 15, and a unipolar operation is performed when the ON control signal is input to both the first control electrode 14 and the second control electrode 15. In the following description, in a case where an ON control signal and an OFF control signal described later are not distinguished, each of them is referred to as “control signal”.

FIG. 2 is a cross-sectional view illustrating a configuration of a related device relevant to the semiconductor device according to the present first preferred embodiment. The related device is a high breakdown voltage semiconductor device with a built-in BSD function. First, in the configuration of the related device in FIG. 2, main points different from the configuration of the semiconductor device according to the present first preferred embodiment will be described.

In the related device, the second main electrode 17 is connected only to the N-type diffusion layer 7, and a third main electrode 20 is connected to the P-type diffusion layer 5 via a P-type diffusion layer 19 having a concentration higher than that in the P-type diffusion layer 5. A lower portion of the P-type diffusion layer 5 is connected to the P-type support substrate 1, and an N-type diffusion layer 18 having a concentration lower than that in the N-type diffusion layer 7 is provided on the upper portion of the P-type diffusion layer 5. A first potential is applied to the first main electrode 16, a second potential is applied to the second main electrode 17, and a third potential is applied to the third main electrode 20. In addition, the first control electrode 14 connected to the first conductive layer 11 is not provided, and the related device is controlled by a signal applied to the second control electrode connected to the second conductive layer 12.

At the time of maintaining the breakdown voltage of the related device, the first potential becomes higher than the second potential, a depletion layer extends from the PN junction between the N-type semiconductor layer 3 as the breakdown voltage maintaining layer and the P-type support substrate 1, and the N-type semiconductor layer 3 is completely depleted, so that the higher breakdown voltage is achieved. Here, the insulating layer 8 and the insulating layer 13 on the N-type semiconductor layer 3, and in addition, the conductor or the electrode provided inside the insulating layer 8 and the insulating layer 13 have an effect of uniforming the electric field in the N-type semiconductor layer 3 and increasing the breakdown voltage.

During BSD operation, the second potential is higher than the first potential, the third potential is equal to or lower than the first potential, hole injection from the P-type diffusion layer 5 to the N-type semiconductor layer 3 and conductivity modulation do not occur, and conduction is established between the first main electrode 16 and the second main electrode 17 by unipolar operation. Therefore, the related device has a disadvantage that the ON resistance is limited to the product of the depth of the N-type semiconductor layer 3 in the vertical direction and the concentration of impurities in the N-type semiconductor layer 3.

In contrast, in the semiconductor device according to the present first preferred embodiment, as illustrated in FIG. 1, the P-type diffusion layer 4 and the first control electrode 14 which is connected to the first conductive layer 11 are provided, and the second main electrode 17 is connected to both the P-type diffusion layer 5 and the N-type diffusion layer 7. A point that the semiconductor device according to the present first preferred embodiment is superior to the related device in FIG. 2 will be described below.

In the semiconductor device according to the present first preferred embodiment, in a case where the second potential of the second main electrode 17 is a high potential and the potential difference between the second potential and the first potential of the first main electrode 16 is relatively large, the ON control signal is not input to the second control electrode 15, but to the first control electrode 14. By this input, an N-type current path is formed in the P-type diffusion layer 4 immediately below the first insulating film 9. At this time, since the PN junction between the P-type diffusion layer 5 and the N-type semiconductor layer 3 is biased in the forward direction, a current flows from the second main electrode 17 to the first main electrode 16, and holes are injected from the P-type diffusion layer 5 to the N-type semiconductor layer 3. That is, conduction is established between the first main electrode 16 and the second main electrode 17 by the bipolar operation.

Here, it is assumed that the potential difference between the first potential and the second potential at the time of maintaining the breakdown voltage is relatively large, for example, 300 V or more, and the length in the lateral direction of the N-type semiconductor layer 3 serving as a current path when conduction is established, that is, the length between the P-type diffusion layer 4 and the P-type diffusion layer 5 is relatively long, for example, 20 μm or more. In such a case, since the voltage drop due to the ON resistance in the N-type semiconductor layer 3 is larger than the voltage drop due to the built-in potential of the PN junction, the bipolar operation is advantageous. In the semiconductor device according to the present first preferred embodiment, since the bipolar operation is performed in the above-described case, the resistance value of the N-type semiconductor layer 3 can be reduced by conductivity modulation as compared with the unipolar operation.

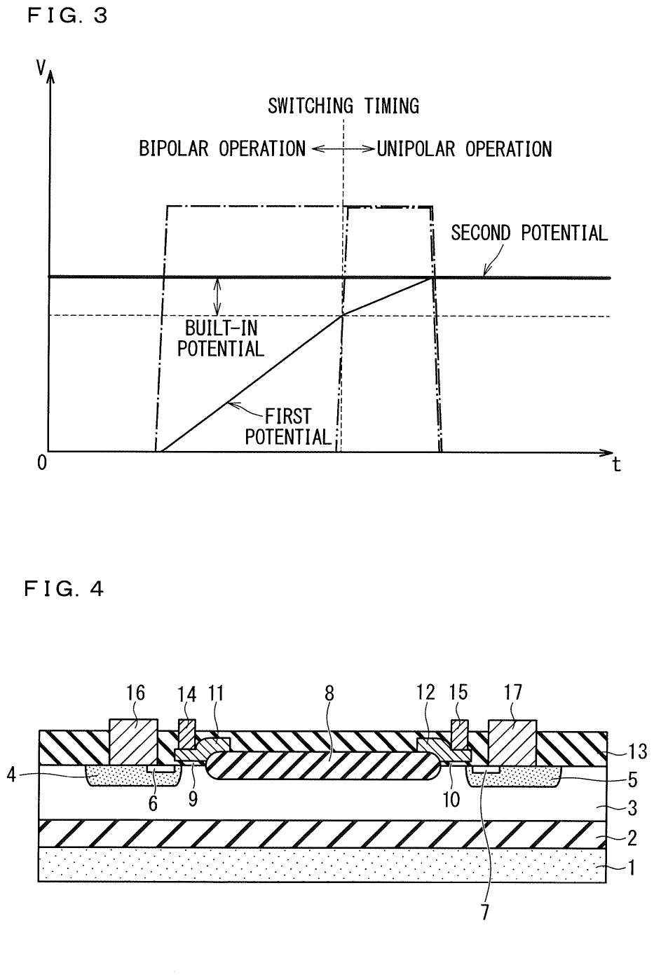

However, in a case where the potential difference between the second potential and the first potential is relatively small, the conduction current between the first main electrode 16 and the second main electrode 17 decreases, and thus, the voltage drop of the built-in potential of the PN junction becomes larger than the voltage drop due to the ON resistance in the N-type semiconductor layer 3. Therefore, in the semiconductor device according to the present first preferred embodiment, a control signal is input as illustrated in FIG. 3. The alternate long and short dash line indicates a control signal input to the first control electrode 14, and the alternate long and two short dashes line indicates a control signal input to the second control electrode 15.

As illustrated in FIG. 3, in a case where the potential difference between the second potential and the first potential is large, the ON control signal is not input to the second control electrode 15, but to the first control electrode 14. On the other hand, in a case where the potential difference between the second potential and the first potential is small, the ON control signal is input not only to the first control electrode 14, but also to the second control electrode 15. By this input, an N-type current path is formed in the P-type diffusion layer 5 immediately below the second insulating film 10, and a bypass is provided between the N-type semiconductor layer 3 and the N-type diffusion layer 7, so that conduction is established between the first main electrode 16 and the second main electrode 17 by unipolar operation. In the semiconductor device according to the present first preferred embodiment, since the unipolar operation is performed in the above-described case, conduction between the first main electrode 16 and the second main electrode 17 can be maintained until the second potential and the first potential become equal.

The predetermined threshold of the potential difference between the second potential and the first potential for switching between the bipolar operation and the unipolar operation may be, for example, 0.5 [V] to 1.0 [V], which is about the same as the built-in potential of the PN junction between the N-type semiconductor layer 3 and the P-type diffusion layer 5. The predetermined threshold may be, for example, 0.6 [V] to 0.8 [V].

The semiconductor device of the present first preferred embodiment may be turned off from the bipolar operation, not via the unipolar operation, and in that case, an OFF control signal at the same timing as that of the first control electrode 14 may be input to the second control electrode. This input can suppress hole injection from the P-type diffusion layer 5 to the N-type semiconductor layer 3 at turn-off, so that switching loss can be reduced.

### Summary of First Preferred Embodiment

As described above, in the semiconductor device according to the present first preferred embodiment, the conduction by the bipolar operation and the conduction by the unipolar operation can be switched between the first main electrode 16 and the second main electrode 17. According to such a configuration, it is possible to achieve both an advantage of reducing the ON resistance by the bipolar operation and an advantage of maintaining conduction by the unipolar operation until the second potential and the first potential become equal.

In the above description, the first control electrode 14 controls ON and OFF of the semiconductor device, and the second control electrode 15 controls switching between the bipolar operation and the unipolar operation, but the present invention is not limited thereto. For example, the control signal applied to the first control electrode 14 and the control signal applied to the second control electrode 15 are exchanged, and the first potential of the first main electrode 16 and the second potential of the second main electrode 17 are exchanged, whereby conduction can be performed in the opposite direction.

### Second Preferred Embodiment

FIG. 4 is a cross-sectional view illustrating a configuration of a semiconductor device according to the present second preferred embodiment. In the present second preferred embodiment, the base layer is the insulating layer 2 made of an insulator, and the insulating layer 2 is provided between the P-type support substrate 1 and the N-type semiconductor layer 3.

According to the configuration of the present second preferred embodiment, since the vertical parasitic PNP operation at the time of maintaining the breakdown voltage in the portion including the P-type diffusion layer 4, the N-type semiconductor layer 3, and the P-type support substrate 1 can be suppressed by the insulating layer 2 as compared with the configuration of the first preferred embodiment, the control electrode drive circuit or the like can be easily designed.

In addition, in the configuration in which the insulating layer 2 is provided under the N-type semiconductor layer 3, since depletion occurs from the interface between the N-type semiconductor layer 3 and the insulating layer 2 at the time of maintaining the breakdown voltage, the N-type support substrate can be provided under the insulating layer 2 instead of the P-type support substrate 1. However, in the configuration in which the N-type support substrate is provided on the lower side of the insulating layer 2, it is necessary to maintain the breakdown voltage inside the insulating layer 2, and the thickness of the entire semiconductor device depends on the dielectric breakdown electric field strength of the material (for example, oxide film) used for the insulating layer 2, so that the thickness is slightly increased. On the other hand, in the configuration in which the P-type support substrate 1 is provided on the lower side of the insulating layer 2, the depletion layer extends from the interface between the P-type support substrate 1 and the insulating layer 2 into the P-type support substrate 1, and the breakdown voltage can be maintained. Therefore, the thickness of the insulating layer 2 can be made thinner than in the configuration in which the N-type support substrate is provided on the lower side of the insulating layer 2. The thickness of the insulating layer 2 may be nonuniform.

### Third Preferred Embodiment

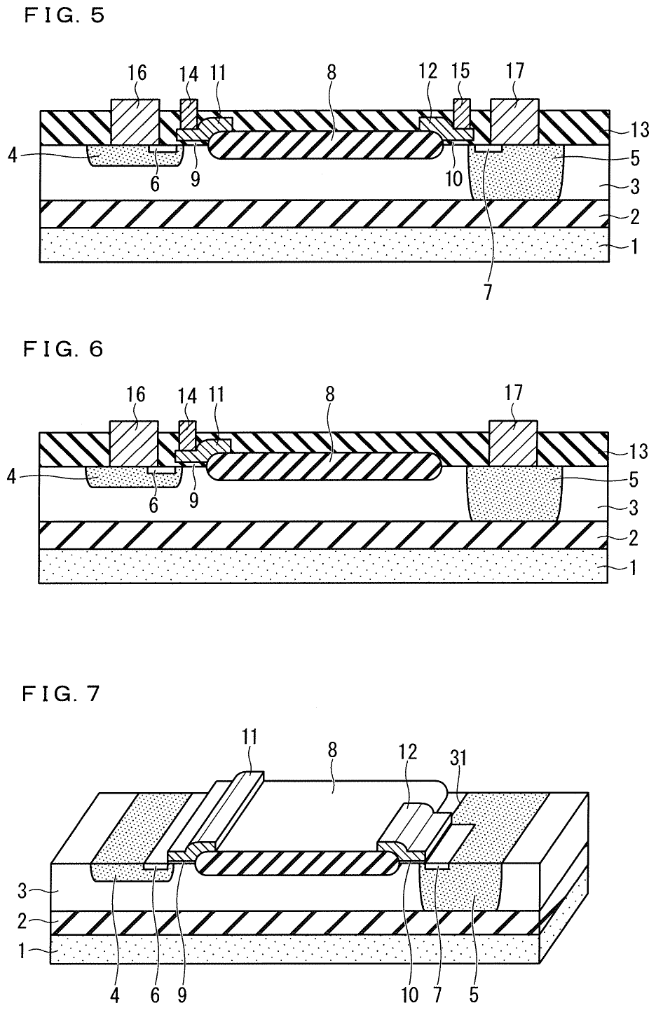

FIG. 5 is a cross-sectional view illustrating a configuration of a semiconductor device according to the present third preferred embodiment. The configuration of the present third preferred embodiment is same as the configuration in which the lower portion of the P-type diffusion layer 5 is connected to the insulating layer 2 in the above-described configuration.

In such a configuration, the interface between the insulating layer 2 and the P-type diffusion layer 5 is connected to the second main electrode 17 via the P-type diffusion layer 5. Therefore, even in a case where the potential of the P-type support substrate 1 is floating without being fixed, depletion can occur from the interface between the insulating layer 2 and the N-type semiconductor layer 3. In addition, since the interface between the N-type semiconductor layer 3 and the P-type diffusion layer 5 is not curved but straight, the electric field concentration at a corner portion is alleviated. As a result, since the concentration of impurities in the N-type semiconductor layer 3 can be increased as compared with the second preferred embodiment, the ON resistance of the N-type semiconductor layer 3 can be reduced.

Note that the P-type diffusion layer 5 and the P-type diffusion layer 4 may be collectively formed by making the concentration of the P-type diffusion layer 5 and the concentration of the P-type diffusion layer 4 the same. However, since the P-type diffusion layer 5 has a role of making the potential of the interface between the insulating layer 2 and the P-type diffusion layer 5 equal to the second potential of the second main electrode 17, depletion at the time of maintaining the breakdown voltage may be suppressed by making the concentration of the P-type diffusion layer 5 higher than the concentration of the P-type diffusion layer 4. As a method of increasing the concentration of the P-type diffusion layer 5, an ion implantation step may be divided, or the P-type diffusion layer 5 and the P-type diffusion layer 4 may be collectively formed by combining the ion implantation amount and changing the implantation efficiency by forming the implantation region of the P-type diffusion layer 4 in a line shape or a dot shape.

### Fourth Preferred Embodiment

FIG. 6 is a cross-sectional view illustrating a configuration of a semiconductor device according to the present fourth preferred embodiment, and FIG. 7 is a perspective view illustrating the configuration.

The configuration of FIG. 7 including the configuration of FIG. 5 of the third preferred embodiment and the configuration of FIG. 6 is repeatedly provided along the direction from the front to the back. Therefore, in plan view, the N-type diffusion layer 7 is provided not continuously but intermittently along a boundary line 31 between the N-type semiconductor layer 3 and the P-type diffusion layer 5 in FIG. 7. Note that, similarly to the first preferred embodiment, in a case where the potential difference between the first potential and the second potential is larger than the built-in potential due to the PN junction between the N-type semiconductor layer 3 and the P-type diffusion layer 5, the bipolar operation is performed by applying the ON control signal only to the second control electrode 15. In a case where the potential difference between the first potential and the second potential is smaller than the built-in potential due to the PN junction between the N-type semiconductor layer 3 and the P-type diffusion layer 5, by applying the ON control signal to both the first control electrode 14 and the second control electrode 15, the bipolar operation is performed substantially only in a portion including the configuration of FIG. 5 in the configuration of FIG. 7.

As illustrated in FIG. 6, the second insulating film 10, the second conductive layer 12, and the second control electrode 15 are not provided in a portion where the N-type diffusion layer 7 is not provided. In such a configuration of FIG. 6, the capacitance of the second control electrode 15 decreases as compared with the configuration of FIG. 5 in which the second conductive layer 12 and the second control electrode 15 are provided. Therefore, in the configuration of FIG. 7 in which the configuration of FIG. 5 and the configuration of FIG. 6 are alternately provided, the trade-off curve between the ON resistance and the switching loss during the unipolar operation and the bipolar operation can be changed by adjusting the ratio between the configuration of FIG. 5 and the configuration of FIG. 6. Therefore, by adjusting the above ratio, it is possible to design the semiconductor device while adjusting the trade-off between the ON resistance and the switching loss to suit the operation frequency of the semiconductor device.

### Fifth Preferred Embodiment

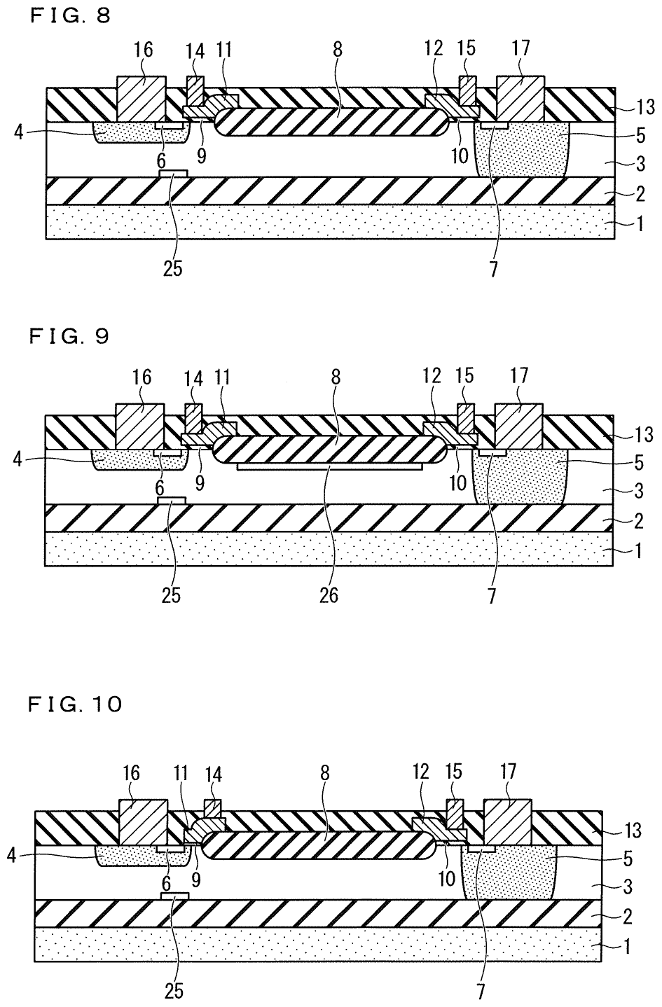

FIG. 8 is a cross-sectional view illustrating a configuration of a semiconductor device according to the present fifth preferred embodiment. In the configuration of the present fifth preferred embodiment, in the above-described configuration, an N-type diffusion layer 25 which is a sixth semiconductor layer of the second conductivity type is provided below the P-type diffusion layer 4 and at the interface between the insulating layer 2 and the N-type semiconductor layer 3. The concentration of N-type impurities in the N-type diffusion layer 25 is higher than the concentration of N-type impurities in the N-type semiconductor layer 3, and the distance between the N-type diffusion layer 25 and the second main electrode 17 in plan view is larger than the distance between the P-type diffusion layer 4 and the second main electrode 17 in plan view.

According to such a configuration, the interface between the N-type semiconductor layer 3 and the insulating layer 2 below the P-type diffusion layer 4 can be suppressed from inducing P-type inversion by the electric field generated from the potential difference with the P-type support substrate 1, so that parasitic operation in the vertical direction can be suppressed. Furthermore, at the time of maintaining the breakdown voltage of the semiconductor device, the depletion layer extending from the interface between the N-type semiconductor layer 3 and the P-type diffusion layer 5 toward the first main electrode 16 can be suppressed from coming into contact with the P-type diffusion layer 4, so that the breakdown voltage can be increased. In order to alleviate the electric field concentration at the end portion of the N-type diffusion layer 25 on the second main electrode 17 side, the concentration of the end portion may be reduced by forming the implantation region at the end portion in a line shape or a dot shape.

### Sixth Preferred Embodiment

FIG. 9 is a cross-sectional view illustrating a configuration of a semiconductor device according to the present sixth preferred embodiment. In the configuration of the present sixth preferred embodiment, in the above-described configuration, an N-type diffusion layer 26 which is a seventh semiconductor layer of the second conductivity type is provided immediately below the insulating layer 8. The concentration of N-type impurities in the N-type diffusion layer 26 is higher than the concentration of N-type impurities in the N-type semiconductor layer 3.

According to such a configuration, since the concentration of impurities in the N-type semiconductor layer 3 that occupies most of the drift length of the semiconductor device when conduction is established increases, the ON resistance during the unipolar operation can be reduced. The concentration distribution of the N-type diffusion layer 26 may be inconstant such that the concentration of the N-type diffusion layer 26 is high on the first main electrode 16 side and low on the second main electrode 17 side, for example. As a method of providing a concentration distribution to the N-type diffusion layer 26, a method of adding an injection step may be used, or a method of forming a low-concentration portion and a high-concentration portion collectively by changing injection efficiency by forming an injection region in a line shape or a dot shape may be used. Furthermore, the N-type diffusion layer 26 may cover the entire portion immediately below the insulating layer 8, or an end portion of the N-type diffusion layer 26 on the second main electrode 17 side may be provided closer to the first main electrode 16 than in FIG. 9.

### Seventh Preferred Embodiment

FIG. 10 is a cross-sectional view illustrating a configuration of a semiconductor device according to the present seventh preferred embodiment. In the seventh preferred embodiment, in the above-described configuration, the first insulating film 9 is thinner in the vertical direction than the second insulating film 10. The distance between the P-type diffusion layer 4 and the insulating layer 8 may be shortened, or the distance between the N-type diffusion layer 6 and the N-type semiconductor layer 3 may be shortened. As a result, since the drive voltage of the first control electrode 14 can be lowered, at least one of the reduction of the switching loss during the ON and OFF operations and the simplification of the drive circuit of the first control electrode 14 can be achieved. When the distance between the N-type diffusion layer 6 and the N-type semiconductor layer 3 is shortened, the concentration of the P-type diffusion layer 4 may be increased so that the depletion layer generated from the interface between the P-type diffusion layer 4 and the N-type semiconductor layer 3 does not come into contact with the N-type diffusion layer 6 when the first potential is lower than the second potential.

### Eighth Preferred Embodiment

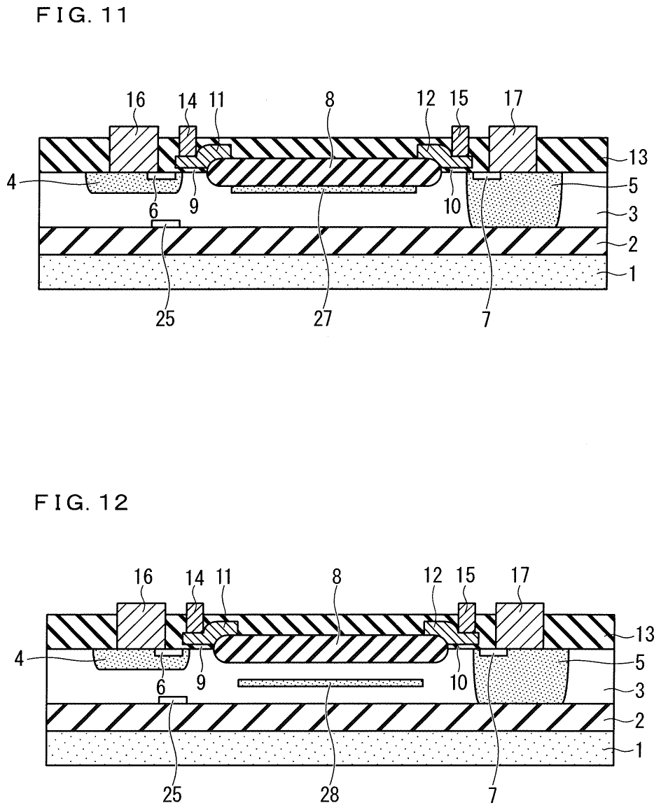

FIG. 11 is a cross-sectional view illustrating a configuration of a semiconductor device according to the present eighth preferred embodiment. In the present eighth preferred embodiment, in the above-described configuration, a P-type diffusion layer 27 which is an eighth semiconductor layer of the first conductivity type is provided immediately below the insulating layer 8.

As a condition for completely depleting the P-type diffusion layer 27, there is a limitation on the product of the depth t in the vertical direction of the P-type diffusion layer 27 and the concentration N of impurities in the P-type diffusion layer 27, and specifically, it is necessary to satisfy a condition of N×t<6.9×10¹¹ cm⁻² (see, e.g., J. A. APPELS, et al., “THIN LAYER HIGH-VOLTAGE DEVICES (RESURF DEVICES), Philips Journal of Research, 1980, Vol. 35, No. 1, P. 4). Therefore, in the present eighth preferred embodiment, the depth t in the vertical direction of the P-type diffusion layer 27 and the concentration N of impurities in the P-type diffusion layer 27 are adjusted so as to satisfy this condition.

By the P-type diffusion layer 27, at the time of maintaining the breakdown voltage, depletion occurs not only from the interface between the insulating layer 2 and the N-type semiconductor layer 3, but also from the interface between the P-type diffusion layer 27 and the N-type semiconductor layer 3, so that the concentration of impurities in the N-type semiconductor layer 3 can be increased. As a result, the ON resistance during the unipolar operation can be reduced. The area in which the impurity concentration is increased in the N-type semiconductor layer 3 may be the entire N-type semiconductor layer 3, but in order to suppress a decrease in breakdown voltage, it is desirable that the area be limited to the area in which the P-type diffusion layer 27 is provided.

The concentration distribution of the P-type diffusion layer 27 may be inconstant such that the concentration of the P-type diffusion layer 27 is high on the first main electrode 16 side and low on the second main electrode 17 side, for example. As a method of providing a concentration distribution to the P-type diffusion layer 27, a method of adding an injection step may be used, or a method of forming a low-concentration portion and a high-concentration portion collectively by changing injection efficiency by forming an injection region in a line shape or a dot shape may be used. Furthermore, the P-type diffusion layer 27 may cover the entire portion immediately below the insulating layer 8, or an end portion of the P-type diffusion layer 27 on the second main electrode 17 side may be provided closer to the first main electrode 16 than in FIG. 11.

### Ninth Preferred Embodiment

FIG. 12 is a cross-sectional view illustrating a configuration of a semiconductor device according to the present ninth preferred embodiment. In the present ninth preferred embodiment, in the above-described configuration, a P-type diffusion layer 28 which is a ninth semiconductor layer of the first conductivity type is provided inside the N-type semiconductor layer 3 below the insulating layer 8.

As a condition for completely depleting the P-type diffusion layer 28, there is a limitation on the product of the depth t in the vertical direction of the P-type diffusion layer 28 and the concentration N of impurities in the P-type diffusion layer 28, and specifically, it is necessary to satisfy a condition of ½×N×t<6.9×10¹¹ cm⁻². Therefore, in the present ninth preferred embodiment, the depth t in the vertical direction of the P-type diffusion layer 28 and the concentration N of impurities in the P-type diffusion layer 28 are adjusted so as to satisfy this condition.

According to such a configuration, at the time of maintaining the breakdown voltage, depletion occurs not only from the interface between the insulating layer 2 and the N-type semiconductor layer 3, but also from the interface between the P-type diffusion layer 28 and the N-type semiconductor layer 3. Since the P-type diffusion layer 28 is provided inside the N-type semiconductor layer 3, depletion occurs from both upper and lower interfaces between the P-type diffusion layer 28 and the N-type semiconductor layer 3, so that the concentration of impurities in the N-type semiconductor layer 3 can be further increased. As a result, the ON resistance during the unipolar operation can be reduced.

The concentration distribution of the P-type diffusion layer 28 may be inconstant such that the concentration of the P-type diffusion layer 28 is high on the first main electrode 16 side and low on the second main electrode 17 side, for example. As a method of providing a concentration distribution to the P-type diffusion layer 28, a method of adding an injection step may be used, or a method of forming a low-concentration portion and a high-concentration portion collectively by changing injection efficiency by forming an injection region in a line shape or a dot shape may be used. Furthermore, the P-type diffusion layer 28 may cover the entire lower portion of the insulating layer 8, or an end portion of the P-type diffusion layer 28 on the second main electrode 17 side may be provided closer to the first main electrode 16 than in FIG. 12.

The P-type diffusion layer 28 may be formed near the center of the N-type semiconductor layer 3 in the vertical direction, but is not limited thereto. For example, when the concentration of impurities in the N-type semiconductor layer 3 is inconstant in the vertical direction, the P-type diffusion layer 28 may be provided so that the product of the depth t in the vertical direction of the N-type semiconductor layer 3 on the upper side of the P-type diffusion layer 28 and the concentration N of impurities in the N-type semiconductor layer 3 on the upper side of the P-type diffusion layer 28 is equal to the product corresponding to the N-type semiconductor layer 3 on the lower side of the P-type diffusion layer 28.

### Tenth Preferred Embodiment

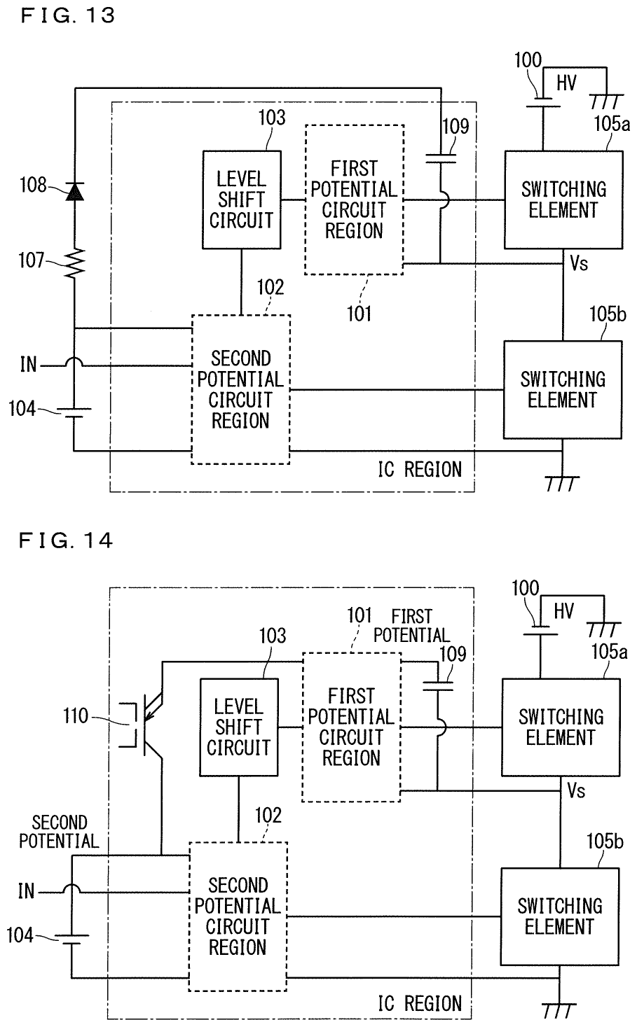

FIG. 13 is a circuit diagram illustrating a configuration of a semiconductor circuit including a general bootstrap circuit. The semiconductor circuit of FIG. 13 includes a power supply 100, a first potential circuit region 101, a second potential circuit region 102, a level shift circuit 103, a power supply 104, switching elements 105a and 105b, a limiting resistor 107, a bootstrap diode 108, and a bootstrap capacitor 109.

The level shift circuit 103 transmits a signal based on an input signal IN from the second potential circuit region 102 to the first potential circuit region 101. The power supply 104 is a power supply for driving the circuit in the second potential circuit region 102. The switching elements 105a and 105b are connected in series between the power supply 100 and the ground, and the circuit in the first potential circuit region 101 and the circuit in the second potential circuit region 102 control the switching elements 105a and 105b, respectively, on the basis of the direct and indirect input signals IN.

The potential Vs between the switching element 105a and the switching element 105b changes from the potential HV of the power supply 100 to the ground potential along with the ON and OFF operations of the switching elements 105a and 105b. The bootstrap capacitor 109 is charged by the power supply 104 when the potential Vs becomes the potential of the ground, and is discharged when the potential Vs becomes the potential HV of the power supply 100. The voltage of the bootstrap capacitor 109 is used as an alternative to the power supply of the circuit in the first potential circuit region 101. When the potential Vs becomes the potential HV of the power supply 100, the bootstrap diode 108 prevents current flow from the bootstrap capacitor 109 into the power supply 104. The limiting resistor 107 limits the current from the power supply 104 to the bootstrap capacitor 109 to a desired value.

FIG. 14 is a circuit diagram illustrating a configuration of a semiconductor circuit according to the present tenth preferred embodiment. In the configuration of FIG. 14, a semiconductor device 110 of any one of the first to ninth preferred embodiments is provided instead of the limiting resistor 107 and the bootstrap diode 108 of FIG. 13. In the semiconductor device 110, the potential of the power supply 104 in the second potential circuit region 102 is used as the second potential of the second main electrode 17, and the potential of the bootstrap capacitor 109 is used as the first potential of the first main electrode 16.

According to such a configuration, the bootstrap diode 108 is replaced by the semiconductor device 110 that performs either the bipolar operation or the unipolar operation. Furthermore, the resistance component of the limiting resistor 107 is replaced by, for example, the ON resistance of the semiconductor device 110. The bootstrap capacitor 109 is electrically connected to such a semiconductor device 110. Although not illustrated, a control unit that inputs a control signal to the semiconductor device 110 may be provided in the semiconductor circuit of FIG. 14.

According to the semiconductor circuit according to the present tenth preferred embodiment as illustrated in FIG. 14, a bootstrap circuit can be configured without using a separate bootstrap diode 108 or the like. In addition, by inputting the ON control signal to the second control electrode 15 in accordance with a desired current value to change the ON resistance of the semiconductor device 110, it is possible to cope with a small current application to a large current application without increasing the chip area.

### Eleventh Preferred Embodiment

In the semiconductor circuit of FIG. 14, in a case where the output frequency of the system to be incorporated is low and the capacitance of the bootstrap capacitor 109 is insufficient, the discharge voltage decreases, and as a result, there is a possibility of causing an increase in loss at the switching elements 105a and 150b and a system shutdown. As a countermeasure, an increase in the capacity or the charging voltage of the bootstrap capacitor 109 is effective, but the former leads to an increase in the system volume, and thus the latter is preferable. Therefore, it is preferable that the charging voltage of the bootstrap capacitor 109 is increased as high as possible.

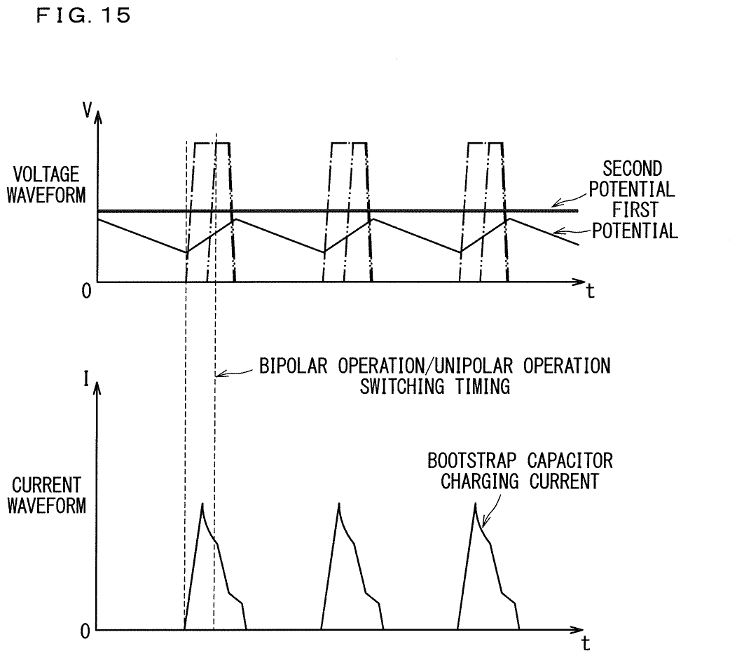

Meanwhile, the semiconductor device 110 has a built-in potential of a PN junction during the bipolar operation. Therefore, in the present eleventh preferred embodiment, as illustrated in FIG. 15, in a case where the potential difference between the second potential and the first potential is larger than a predetermined threshold, the ON control signal is input to one of the first control electrode 14 and the second control electrode 15 to cause the semiconductor device 110 to perform the bipolar operation. Then, in a case where the potential difference is smaller than the threshold, the ON control signal is input to both the first control electrode 14 and the second control electrode 15 to cause the semiconductor device 110 to perform the unipolar operation.

In the example of FIG. 15, after the semiconductor device 110 is caused to perform the unipolar operation, in a case where the potential difference between the second potential and the first potential becomes smaller than another threshold that is smaller than the threshold, the OFF control signal is input to both the first control electrode 14 and the second control electrode 15. When the OFF control signal is input, the bootstrap capacitor 109 is discharged and the first potential decreases.

The predetermined threshold is the same value as the built-in potential of the PN junction or a value smaller than the built-in potential. The predetermined threshold may be an actual measurement value of the built-in potential or a value obtained empirically.

According to the above-described configuration, the charging voltage of the bootstrap capacitor 109 can be increased by switching between the bipolar operation and the unipolar operation. Note that, in a case where the maximum value of the potential difference between the second potential and the first potential is 1.0 [V] or less, there are few regions where the semiconductor device 110 works in the bipolar operation, and the effect of reducing the ON resistance is not obtained much. Therefore, in such a case, the semiconductor device 110 may charge the bootstrap capacitor 109 only in the unipolar operation.

Note that each preferred embodiment and each modification can be freely combined, and each preferred embodiment and each modification can be appropriately modified or omitted.

Hereinafter, various aspects of the present disclosure will be collectively described as appendices.

### Appendix 1

A semiconductor device comprising:

a base layer made of a semiconductor of a first conductivity type or an insulator;

a first semiconductor layer of a second conductivity type provided on the base layer;

a second semiconductor layer of the first conductivity type and a third semiconductor layer of the first conductivity type provided separately from each other on an upper portion of the first semiconductor layer;

a fourth semiconductor layer of the second conductivity type provided on an upper portion of the second semiconductor layer and sandwiching a part of the second semiconductor layer with the first semiconductor layer;

a fifth semiconductor layer of the second conductivity type provided on an upper portion of the third semiconductor layer and sandwiching a part of the third semiconductor layer with the first semiconductor layer;

an insulating layer provided on an upper portion of the first semiconductor layer between the second semiconductor layer and the third semiconductor layer;

a first conductive portion provided on the part of the second semiconductor layer via a first insulating film;

a second conductive portion provided on the part of the third semiconductor layer via a second insulating film;

a first main electrode electrically connected to the second semiconductor layer and the fourth semiconductor layer; and

a second main electrode electrically connected to the third semiconductor layer and the fifth semiconductor layer, wherein

when an ON control signal is input to one of the first conductive portion and the second conductive portion, conduction is established between the first main electrode and the second main electrode by a bipolar operation, and when the ON control signal is input to both the first conductive portion and the second conductive portion, conduction is established between the first main electrode and the second main electrode by a unipolar operation.

### Appendix 2

The semiconductor device according to appendix 1, wherein the material of the base layer is an insulator.

### Appendix 3

The semiconductor device according to appendixes 1 or 2, wherein a lower portion of the third semiconductor layer is connected to the base layer.

### Appendix 4

The semiconductor device according to any one of appendixes 1 to 3, wherein the fifth semiconductor layer is intermittently provided along a boundary line between the first semiconductor layer and the third semiconductor layer in plan view.

### Appendix 5

The semiconductor device according to any one of appendixes 1 to 4, further comprising a sixth semiconductor layer of the second conductivity type provided below the second semiconductor layer and at an interface between the base layer and the first semiconductor layer, wherein

a concentration of impurities of the second conductivity type in the sixth semiconductor layer is higher than a concentration of impurities of the second conductivity type in the first semiconductor layer, and

a distance between the sixth semiconductor layer and the second main electrode in plan view is larger than a distance between the second semiconductor layer and the second main electrode in plan view.

### Appendix 6

The semiconductor device according to any one of appendixes 1 to 5, further comprising a seventh semiconductor layer of the second conductivity type provided immediately below the insulating layer, wherein

a concentration of impurities of the second conductivity type in the seventh semiconductor layer is higher than a concentration of impurities of the second conductivity type in the first semiconductor layer.

### Appendix 7

The semiconductor device according to any one of appendixes 1 to 6, wherein the first insulating film is thinner than the second insulating film in a vertical direction.

### Appendix 8

The semiconductor device according to any one of appendixes 1 to 7, further comprising an eighth semiconductor layer of the first conductivity type provided immediately below the insulating layer, wherein

N×t<6.9×10¹¹ cm⁻² holds in a case where a thickness of the eighth semiconductor layer in a vertical direction is t and a concentration of impurities in the eighth semiconductor layer is N.

### Appendix 9

The semiconductor device according to any one of appendixes 1 to 7, further comprising a ninth semiconductor layer of the first conductivity type provided inside the first semiconductor layer below the insulating layer, wherein

½×N×t<6.9×10¹¹ cm⁻² holds in a case where a thickness of the ninth semiconductor layer in a vertical direction is t and a concentration of impurities in the ninth semiconductor layer is N.

### Appendix 10

A semiconductor circuit comprising:

the semiconductor device according to any one of appendixes 1 to 9; and

a bootstrap capacitor electrically connected to the semiconductor device.

### Appendix 11

A method of controlling the semiconductor device according to any one of appendixes 1 to 10, wherein

in a case where a potential difference between a first potential of the first conductive portion and a second potential of the second conductive portion is larger than a predetermined threshold, the ON control signal is input to one of the first conductive portion and the second conductive portion, and

in a case where the potential difference is smaller than the threshold, the ON control signal is input to both the first conductive portion and the second conductive portion.

While the disclosure has been shown and described in detail, the foregoing description is in all aspects illustrative and not restrictive. It is therefore understood that numerous modifications and variations can be devised.

What is claimed is:

1. A semiconductor device comprising:
a base layer made of a semiconductor of a first conductivity type or an insulator;
a first semiconductor layer of a second conductivity type provided on the base layer;
a second semiconductor layer of the first conductivity type and a third semiconductor layer of the first conductivity type provided separately from each other on an upper portion of the first semiconductor layer;
a fourth semiconductor layer of the second conductivity type provided on an upper portion of the second semiconductor layer and sandwiching a part of the second semiconductor layer with the first semiconductor layer;
a fifth semiconductor layer of the second conductivity type provided on an upper portion of the third semiconductor layer and sandwiching a part of the third semiconductor layer with the first semiconductor layer;
an insulating layer provided on an upper portion of the first semiconductor layer between the second semiconductor layer and the third semiconductor layer;
a first conductive portion provided on the part of the second semiconductor layer via a first insulating film;
a second conductive portion provided on the part of the third semiconductor layer via a second insulating film;
a first main electrode electrically connected to the second semiconductor layer and the fourth semiconductor layer; and
a second main electrode electrically connected to the third semiconductor layer and the fifth semiconductor layer, wherein
when an ON control signal is input to one of the first conductive portion and the second conductive portion, conduction is established between the first main electrode and the second main electrode by a bipolar operation, and when the ON control signal is input to both the first conductive portion and the second conductive portion, conduction is established between the first main electrode and the second main electrode by a unipolar operation.

2. The semiconductor device according to claim 1, wherein
the material of the base layer is an insulator.

3. The semiconductor device according to claim 2, wherein
a lower portion of the third semiconductor layer is connected to the base layer.

4. The semiconductor device according to claim 1, wherein
the fifth semiconductor layer is intermittently provided along a boundary line between the first semiconductor layer and the third semiconductor layer in plan view.

5. The semiconductor device according to claim 1, further comprising a sixth semiconductor layer of the second conductivity type provided below the second semiconductor layer and at an interface between the base layer and the first semiconductor layer, wherein
a concentration of impurities of the second conductivity type in the sixth semiconductor layer is higher than a concentration of impurities of the second conductivity type in the first semiconductor layer, and
a distance between the sixth semiconductor layer and the second main electrode in plan view is larger than a distance between the second semiconductor layer and the second main electrode in plan view.

6. The semiconductor device according to claim 1, further comprising a seventh semiconductor layer of the second conductivity type provided immediately below the insulating layer, wherein
a concentration of impurities of the second conductivity type in the seventh semiconductor layer is higher than a concentration of impurities of the second conductivity type in the first semiconductor layer.

7. The semiconductor device according to claim 1, wherein the first insulating film is thinner than the second insulating film in a vertical direction.

8. The semiconductor device according to claim 1, further comprising an eighth semiconductor layer of the first conductivity type provided immediately below the insulating layer, wherein
N×t<6.9×10¹¹ cm⁻² holds in a case where a thickness of the eighth semiconductor layer in a vertical direction is t and a concentration of impurities in the eighth semiconductor layer is N.

9. The semiconductor device according to claim 1, further comprising a ninth semiconductor layer of the first conductivity type provided inside the first semiconductor layer below the insulating layer, wherein
½×N×t<6.9×10¹¹ cm⁻² holds in a case where a thickness of the ninth semiconductor layer in a vertical direction is t and a concentration of impurities in the ninth semiconductor layer is N.

10. A semiconductor circuit comprising:
the semiconductor device according to claims 1; and
a bootstrap capacitor electrically connected to the semiconductor device.

11. A method of controlling the semiconductor device according to claim 1, wherein
in a case where a potential difference between a first potential of the first conductive portion and a second potential of the second conductive portion is larger than a predetermined threshold, the ON control signal is input to one of the first conductive portion and the second conductive portion, and
in a case where the potential difference is smaller than the threshold, the ON control signal is input to both the first conductive portion and the second conductive portion.
